(19) United States
(12) Patent Application Publication
(10) Pub. No.: US 2010/0327317 A1
(43) Pub. Date: Dec. 30, 2010

(54) Germanium on insulator using compound semiconductor barrier layers

(76) Inventors: Ravi Pillarisetty, Portland, OR (US); Mantu Hudait, Portland, OR (US); Marko Radosavljevic, Beaverton, OR (US); Benjamin Chu-Kung, Hillsboro, OR (US); Jack Kavalieros, Portland, OR (US)

Correspondence Address: INTEL CORPORATION;c/o CPA Global, P.O. BOX 52050, MINNEAPOLIS, MN, 55402, US

(21) Appl. No.: 12/459,262

(22) Filed: Jun. 26, 2009

(51) Int. Cl. H01L 29/12; H01L 29/772; H01L 21/336

(52) U.S. Cl. 257/192; 438/151; 257/616; 257/E29.068; 257/E29.242; 257/E21.411

(57) ABSTRACT

Embodiments of an apparatus and methods for providing germanium on insulator using a large bandgap barrier layer are generally described herein. Other embodiments may be described and claimed.

### FIELD OF THE INVENTION

The field of invention relates generally to the field of semiconductor integrated circuit manufacturing and, more specifically but not exclusively, relates to forming a germanium on insulator substrate using a compound semiconductor barrier layer.

### BACKGROUND INFORMATION

Generally, semiconductor substrates comprise semiconductor materials upon which devices may be formed, such as field effect transistors. Semiconductor substrates comprising germanium are emerging as material structures upon which transistor devices may be formed for electronic devices.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a cross-sectional view of a layered substrate, according to an embodiment.

FIG. 2 is a flowchart describing one embodiment of a fabrication process used to form a germanium on insulator (GOI) substrate, according to an embodiment.

FIGS. 3 through 6 are cross-sections illustrating the fabrication of a GOI substrate, according to an embodiment.

FIG. 7 is a block diagram of a system with a central processing unit comprising a layered substrate, according to an embodiment.

### DETAILED DESCRIPTION

Various embodiments of an apparatus and methods for forming a layered substrate using compound semiconductor layers are illustrated and described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

Germanium is a semiconducting material with potential for uses in future generation transistor technology because germanium has relatively high carrier mobility as compared to silicon. Performance of semiconducting devices such as planar and multi-gate transistors can be improved by forming the transistors on a germanium layer that is isolated from an underlying substrate. It would be useful to incorporate germanium in transistors in a manner that avoids degradation to OFF state leakage due to a band-to-band tunneling mechanism. This mechanism can be particularly difficult to overcome since a bandgap of germanium is relatively narrow as compared to other semiconductor materials, including silicon.

It would be an advance in the art of semiconductor device manufacturing to provide a method to form a germanium on insulator (GOI) stack on a substrate. The germanium on insulator stack may allow formation of device features on the structure while avoiding OFF state leakage issues that may otherwise occur. The bandgap of the germanium on insulator stack can be increased by including a large bandgap barrier layer that is lattice matched to one or more adjoining layers. Lattice matching of the layers adjoining the large bandgap barrier layer may avoid defectivity issues related to epitaxial growth of these layers on a silicon substrate. It would be a further advance in the art to grow the germanium on insulator substrate in a cost effective manner in a manufacturing environment. These benefits may result from the apparatus and methods described below.

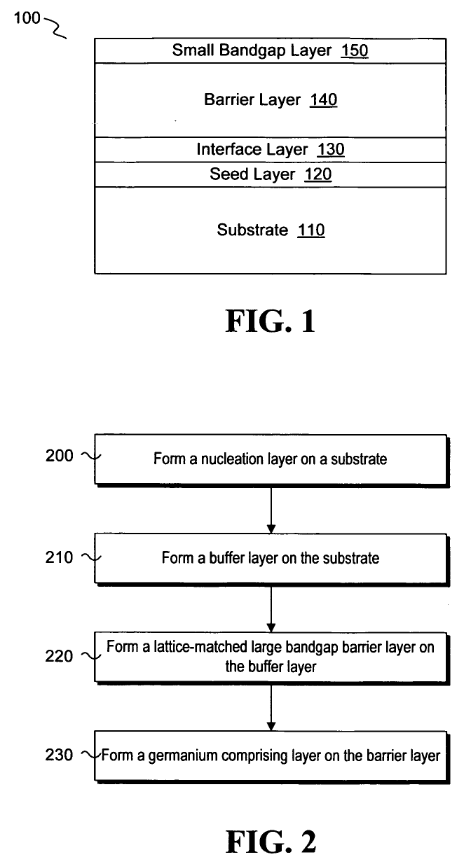

Now turning to the figures, FIG. 1 is a cross-sectional view of a layered substrate 100 comprising germanium or an alloy thereof. The layered substrate 100 may be used in the production of a variety of semiconductor devices, such as a field effect transistor (FET). In an embodiment, the layered substrate 100 comprises a doped or un-doped substrate 110, a seed layer 120, an interface layer 130, a barrier layer 140, and a small bandgap layer 150. In an embodiment, substrate 110 comprises p-type and/or n-type dopant. Dopants including boron, phosphorous, or arsenic, for example, may be introduced in a variety of ways including, for example, diffusion during ingot manufacture or various subsequent diffusion and/or implant processes.

The substrate 110 may comprise a bulk silicon substrate. In another embodiment, the substrate 110 may comprise other materials—which may or may not be combined with silicon—such as: germanium, indium antimonide, lead telluride, indium arsenide, indium phosphide, gallium arsenide, or gallium antimonide. Although a few examples of materials from which substrate 110 may be formed are described here, any material that may serve as a foundation upon which a semiconductor device may be built falls within the scope of the present invention.

An interface layer 130 is formed on the substrate 110 to provide a transition in lattice size between the substrate 110 and layers formed over the interface layer 130, including the barrier layer 140 and the small bandgap layer 150. In one embodiment, the interface layer 130 is formed using a two-stage epitaxial process wherein a very thin seed layer 120 is formed prior to forming the interface layer 130. For example, a compound such as gallium arsenide (GaAs) is initially applied to the substrate 110 using an epitaxial process to form nucleation sites on a surface of the substrate 110. The seed layer 120 is illustrated in FIG. 1 to indicate formation of the interface layer 130 as a two-phase process, however the embodiment is not so limited. The interface layer 130 may alternately be formed as a continuous film in a single process.

The barrier layer 140 is formed of a large bandgap compound material on the interface layer 130 to provide a relatively large bandgap layer on the interface layer 130. The layered substrate 100 further comprises a small bandgap layer 150 or thin film of germanium (Ge) or an alloy comprising germanium such as silicon germanium (SiGe). In an embodiment, the small bandgap layer 150 is physically coupled to the barrier layer 140 and may be epitaxially grown on the barrier layer 140. In this embodiment, the seed layer 120, the interface layer 130, the barrier layer 140, and the small bandgap layer 150 are all formed of materials having similar lattice size, wherein a lattice mismatch between the layers is approximately less than 2%.

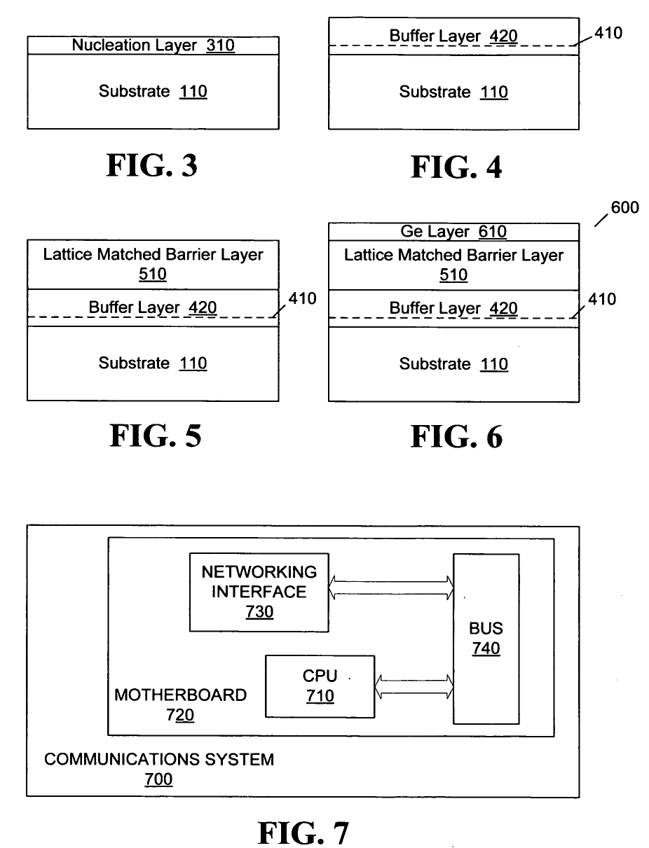

FIG. 2 is a flowchart describing one embodiment of a fabrication process used to form a germanium on insulator (GOI) substrate, which is a form of the layered substrate 100. FIGS. 3 through 6 are cross-sections that further illustrate an embodiment of the germanium on insulator (GOI) substrate, according to the method of FIG. 2. As described in element 200, a nucleation layer 310 illustrated in FIG. 3 is formed on the substrate 110. The nucleation layer 310 is a first portion of a buffer layer 420 of FIG. 4 comprising a material having a first lattice size, wherein the buffer layer 420 is used to form a transition between the underlying substrate 110, having a second lattice size, and a lattice matched barrier layer 510, as illustrated in FIG. 5.

As an example, the nucleation layer 310 is formed of a compound such as gallium arsenide (GaAs) on the substrate 110. The substrate 110 may be prepared using standard surface preparation techniques prior to formation of the nucleation layer 310. The nucleation layer 310 may be formed using one or more techniques designed to reduce dislocation density in the nucleation layer 310. One or more of the following techniques may be used or combined such as forming the nucleation layer 310 followed by a thermal anneal process, inserting a strained-layer superlattice as an intermediate layer between the substrate 110 and the nucleation layer 310, or through low temperature growth of the nucleation layer 310 on the substrate 110.

The nucleation layer 310 may be formed using one or more process methods such as atomic layer epitaxy (ALE) and metalorganic chemical vapor deposition (MOCVD). In an example where ALE is used to form the nucleation layer 310, gallium and arsenic precursors such as trimethylgallium and arsine respectively are serially injected in an epitaxy chamber to control the growth rate of the nucleation layer 310.

Following formation of the nucleation layer 310, the remainder of the buffer layer 420 having a first lattice size is formed, for example by injecting gallium and arsenic precursors in parallel or at the same time in a MOCVD process, to provide a buffer layer 420 thickness ranging between 0.5 to 2.0 microns (μm) or more preferably 0.5 μm or less in thickness. An interface 410 may remain in the buffer layer 420, illustrated in FIG. 4 at a top of the nucleation layer 310 and a bottom of a remaining portion of the buffer layer 420. The interface 410 is illustrated in FIG. 4 as a dashed line, however the buffer layer 420 may have no discernable physical artifact of the interface 410 once formed that would otherwise indicate formation of the buffer layer 420 after initially forming the nucleation layer 310.

A thickness of the buffer layer 420 is established, based at least in part, on a dislocation density requirement of the buffer layer 420 at an interface between the buffer layer 420 and an overlying lattice matched barrier layer 510. For example, the thickness of the buffer layer 420 is established in a range between 0.5 to 2.0 μm to provide a nearly defect free interface between the buffer layer 420 and the lattice matched barrier layer 510. Described another way, the thickness of the buffer layer 420 may be established to prevent propagation of dislocation defects from the nucleation layer 310 through the buffer layer 420 to the lattice matched barrier layer 510 and any overlying layers.

In one embodiment, the lattice matched barrier layer 510 may be formed using an epitaxial process on the buffer layer 420. The lattice matched barrier layer 510 may be an insulator formed of a compound material with a relatively large bandgap to suppress either electron or hole conduction between an overlying germanium (Ge) layer 610 illustrated in FIG. 6 and the substrate 110. The lattice matched barrier layer 510 is formed of a material having a crystal lattice size that is equal to or that closely matches a lattice size of the Ge layer 610. Suppression of electron or hole conduction by the lattice matched barrier layer 510 may be effective in a structure that benefits from the suppression of band to band tunneling leakage, such as in a high mobility field effect transistor (FET) comprising Ge. For example, the lattice matched barrier layer 510 may be formed of aluminum arsenide (AlAs) to provide a relatively large bandgap while providing a lattice size that is equal to or that closely matches a lattice size of the Ge layer 610, allowing formation of a virtually defect free Ge layer 610 that is nearly void of dislocation and other lattice defects.

The Ge layer 610 is comprised of one material that may be used to form a small bandgap layer that is epitaxially coupled to the lattice matched barrier layer 510. In one embodiment, the Ge layer 610 comprises a stack of layers grown at a pressure ranging between 10-150 Torr (T) using a carrier gas such as hydrogen (H2) at a flow ranging between 10-40 standard liters per minute (slm) using an epitaxial deposition process using a deposition tool such as an Applied Materials Centura® or an ASM Epsilon® tool. One or more layers including the nucleation layer 310, the buffer layer 420, the lattice matched barrier layer 510, and the Ge layer 610 may be deposited sequentially in the same reactor or as individual processes to form a germanium on insulator (GOI) substrate 600.

The buffer layer 420, the lattice matched barrier layer 510, and the germanium layer 610 are selectively formed using materials to provide approximately 2% or less lattice mismatch and to provide a layered substrate 100 having a virtually defect-free germanium layer 610. The Ge layer 610 and the lattice matched barrier layer 510 are lattice matched to the buffer layer 420 if there is approximately 2% or less lattice mismatch between the Ge layer 610, the lattice matched barrier layer 510, and the buffer layer 420.

FIG. 7 illustrates a communications system 700 with a central processing unit (CPU) 710 for processing data comprising transistors on a germanium on insulator (GOI) substrate 600 in accordance with one embodiment. The communications system 700 further includes a motherboard 720 with the CPU 710, and a networking interface 730 coupled to a bus 740. More specifically, the CPU 710 may comprise the germanium on insulator substrate 600 and/or its method of fabrication.

Depending on the applications, the communications system 700 may additionally include other components, including but are not limited to volatile and non-volatile memory, a graphics processor, a digital signal processor, a crypto processor, a chipset, mass storage (such as hard disk, solid state drive (SSD), compact disk (CD), digital versatile disk (DVD)), and so forth. One or more of these components may also include the earlier described germanium on insulator substrate 600 and/or its method of fabrication. In various embodiments, the communications system 700 may be a personal digital assistant (PDA), a mobile device, a tablet computing device, a laptop computing device, a desktop computing device, a netbook, a set-top box, an entertainment control unit, a digital camera, a digital video recorder, a CD player, a DVD player, or other digital device of the like.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting.

For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a layered substrate, comprising:
forming an interface layer with a first lattice size on a substrate having a second lattice size;
forming a barrier layer on the interface layer, the barrier layer comprising a large bandgap compound material; and
forming a small bandgap layer on the barrier layer, wherein the small bandgap layer, the barrier layer, and the buffer layer have a similar lattice size.

2. The method of claim 1, further including forming the interface layer on a seed layer.

3. The method of claim 2, wherein a lattice mismatch between the small bandgap layer, the barrier layer, and the buffer layer is approximately less than 2%.

4. The method of claim 1, wherein the substrate comprises silicon.

5. The method of claim 1, further including forming a field effect transistor (FET) on the layered substrate.

6. The method of claim 5, wherein the barrier layer reduces off-state leakage of the FET.

7. A method of forming a germanium on insulator substrate, comprising forming a buffer layer on a substrate, forming a lattice matched barrier layer on the buffer layer, and forming a germanium layer on the lattice matched barrier layer, wherein the buffer layer provides lattice size relief between the substrate and the lattice matched barrier layer.

8. The method of claim 7, wherein the buffer layer comprises a nucleation layer.

9. The method of claim 7, wherein a lattice mismatch between the germanium layer, the lattice matched barrier layer, and the buffer layer is approximately less than 2%.

10. The method of claim 7, wherein the substrate comprises silicon.

11. The method of claim 7, further including forming a field effect transistor (FET) on the germanium on insulator substrate.

12. The method of claim 7, wherein the lattice matched barrier layer is formed of aluminum arsenide (AlAs).

13. A layered substrate, comprising:
a buffer layer with a first lattice size on a substrate having a second lattice size;
a lattice matched barrier layer on the buffer layer; and
a germanium layer on the lattice matched barrier layer, wherein the lattice matched barrier layer and the germanium layer are lattice matched to the buffer layer having the first lattice size.

14. The layered substrate of claim 13, wherein the germanium layer is virtually defect free.

15. The layered substrate of claim 13, wherein the buffer layer is formed of gallium arsenide (GaAs).

16. The layered substrate of claim 15, wherein a thickness of the buffer layer ranges approximately between 0.5 to 2.0 microns (μm).

17. The layered substrate of claim 15, wherein a thickness of the buffer layer is less than 0.5 microns (μm).

18. The layered substrate of claim 13, wherein the lattice matched barrier layer is formed of aluminum arsenide (AlAs).

19. The layered substrate of claim 18, wherein a lattice mismatch between the lattice matched barrier layer, the germanium layer, and the buffer layer is approximately less than 2%.

20. The layered substrate of claim 19, further including a field effect transistor on the layered substrate.
